(19) United States
(12) Patent Application Publication
(10) Pub. No.: US 2023/0104659 A1
(43) Pub. Date: Apr. 6, 2023

(54) BLUE PHOTON COUPLING IMPROVEMENT IN LAYER-STRUCTURED CERAMIC CONVERTER

(71) Applicant: OSRAM Opto Semiconductors GmbH, Regensburg (DE)

(72) Inventors: Zhengbo YU, Shrewsbury, MA (US); Jeffery SERRE, Peabody, MA (US)

(21) Appl. No.: 17/492,719

(22) Filed: Oct. 4, 2021

(51) Int. Cl. H01L 33/50

(52) U.S. Cl. CPC H01L 33/508; H01L 33/502; H01L 2933/0083; H01L 2933/0041

(57) ABSTRACT

A ceramic wavelength converter assembly may include two first layers having an undoped host material or a doped host material, two second layers having a barrier material and being disposed between the two first layers, and a third layer having an undoped host material or a doped host material and being disposed between the two second layers. The two first layers may include the undoped host material and the third layer may include the doped host material, or the two first layers may include the doped host material and the third layer may include the undoped host material. At least one of the two first layers may have a patterned structure.

### TECHNICAL FIELD

The present disclosure relates to ceramic wavelength converter assemblies and light emitting devices comprising ceramic wavelength converter assemblies having a patterned surface.

### BACKGROUND

In most lighting applications based on LEDs (light emitting diodes), the blue light emitted by an InGaN LED is absorbed by a luminescent material (phosphor) that can re-emit the absorbed energy in the form of photons with a longer wavelength and lower energy. Such assemblies can also be called “down-converters”. When down-converters are chosen properly, the resulting LED can emit light of different colors depending on the specific combination of transmitted blue light from the LED plus other colors emitted from one or more phosphors present as luminescent material.

For the most part, down-converters come in two forms: as a powder of a luminescent material (e.g. phosphors or quantum dots) dispersed in a silicone matrix or as a ceramic made from the luminescent material itself. The former is usually more economical, while the latter provides much better thermal stability, needed for applications where light sources with a small footprint are needed.

The efficiency of the LED device is the result of many different factors including how well the LED transforms electricity into blue photons and how well the down-converter transforms them into photons of lower energy. The interaction between the down-converter and the LED is also crucial so that there is an efficient transfer of blue photons from LED to down-converter and extraction of the produced radiation out of the system. For example, a down-converter that reflects strongly will send some of the blue photons back to the LED where they can be reabsorbed and transformed into heat.

Likewise, light that is not efficiently extracted from the LED and the down-converter system will contribute to similar losses. For this reason, coupling of blue photons from the LED to the phosphors and efficient extraction of photons from the device is a matter of great importance.

Layer-structured ceramic converters are described e.g., in U.S. Pat. No. 10,873,009 B2 and U.S. Pat. No. 11,069,841 B2.

Ceramic conversion elements are described e.g., in U.S. Pat. No. 9,102,875,B2 and U.S. Pat. No. 10,862,008 B2.

Herein is described a method to improve the coupling of blue light to ceramic down-converters by patterning the surface of the ceramic down-converters.

### SUMMARY

It is an object to obviate the disadvantages of the prior art.

It is another object to provide a ceramic wavelength converter assembly that might be used in LED applications.

It is a further object to provide a light emitting device comprising at least one ceramic wavelength converter assembly.

It is a further object to provide a method for producing a ceramic wavelength converter assembly.

It is a further object to provide a use of a ceramic wavelength converter assembly.

In accordance with one object, there is provided a ceramic wavelength converter assembly having a layered structure, the ceramic wavelength converter assembly comprising two first layers comprising an undoped host material or a doped host material, two second layers comprising a barrier material and being disposed between the two first layers, and a third layer comprising an undoped host material or a doped host material and being disposed between the two second layers. The two first layers may include the undoped host material and the third layer comprises the doped host material, or the two first layers may include the doped host material and the third layer may include the undoped host material. At least one of the two first layers may have a patterned structure.

In accordance with another object, there is provided a light emitting device comprising a light-emitting structure configured to emit a primary light having a first peak wavelength, and a ceramic wavelength converter assembly positioned to receive the primary light from the light-emitting structure. The ceramic wavelength converter assembly may include two first layers having an undoped host material or a doped host material, two second layers comprising a barrier material and being disposed between the two first layers, and a third layer comprising a doped host material or an undoped host material and being disposed between the two second layers. The two first layers may include the undoped host material and the third layer may include the doped host material, or the two first layers may include the doped host material and the third layer comprises the undoped host material. At least one of the two first layers may have a patterned structure.

In accordance with another object, there is provided a method for producing a ceramic wavelength converter assembly having a layered structure that includes two first layers, two second layers, and a third layer. The method may include providing the third layer comprising a doped host material or an undoped host material, applying the second layer on an upper side of the third layer and applying a second layer on a lower side of the third layer where the second layer includes a barrier material, applying the first layer on a side of the second layers furthest from the the third layer where the first layer comprises an undoped host material or a doped host material, and patterning at least one of the two first layers. The two first layers may include the undoped host material and the third layer may include the doped host material or the two first layers may include the doped host material and the third layer may include the undoped host material.

In accordance with another object, there is provided a use of a ceramic wavelength converter assembly in a light emitting device.

### BRIEF DESCRIPTION OF THE DRAWINGS

FIGS. 1A, 1B and 1C are schematic drawings of ceramic wavelength converter assemblies.

FIG. 2 is a schematic drawing of structure elements.

FIGS. 3A, 3B and 3C show the conversion line, the relationship between the color point and the conversion efficiency of different patterning conditions of exemplary embodiments. FIG. 3A shows the conversion lines for different surface patterning conditions. FIG. 3B shows the conversion lines of patterned vs. unpatterned samples. FIG. 3C shows the relationship between the color point and the conversion efficiency for different patterning conditions.

FIGS. 4A, 4B and 4C show the blue photon absorptions for samples with and without surface patterning and tested under different conditions. FIG. 4A shows the blue photons absorptions for samples with patterning and samples without patterning. The samples are without glue and cast. FIG. 4B shows the blue photon absorptions comparison for samples with patterning and samples without patterning. The samples are glued only. FIG. 4C shows the blue photon absorptions of samples with and samples without patterning. The samples are glued and casted.

FIGS. 5A-5D show SEM images presenting the surface patterning profiles of ceramic wavelength converter assemblies.

FIGS. 6A-6C show exemplary embodiments of light emitting devices.

FIG. 7 shows a schematic overview of a method for producing a ceramic wavelength converter assembly having a layered structure.

### DETAILED DESCRIPTION

For a better understanding, together with other and further objects, advantages and capabilities thereof, reference is made to the following disclosure and appended claims taken in conjunction with the above-described drawings.

References to the color of the phosphor, LED, or conversion material refer generally to its emission color unless otherwise specified. Thus, a blue LED emits a blue light, a yellow phosphor emits a yellow light and so on.

A a ceramic wavelength converter assembly may have or include a layered structure, the ceramic wavelength converter assembly comprising two first layers comprising an undoped host material, or a doped host material, two second layers comprising a barrier material and being disposed between the two first layers, and a third layer comprising an undoped host material, or a doped host material and being disposed between the two second layers, wherein the two first layers comprise the undoped host material and the third layer comprises the doped host material, or wherein the two first layers comprise the doped host material and the third layer comprises the undoped host material, wherein at least one of the two first layers comprise a patterned structure.

In an embodiment, the two first layers comprise a doped host material and the third layer comprises an undoped host material.

In an alternative embodiment, the two first layers comprise an undoped host material and the third layer comprises a doped host material.

As used herein a wavelength converter is a solid structure that converts at least part of the light of a certain first wavelength to light of a certain second wavelength. An assembly is the composite of different materials. In general a ceramic wavelength converter assembly is a composite of different materials comprising at least one ceramic material to convert at least part of the light of a certain first wavelength to light of a certain second wavelength.

The ceramic wavelength converter assembly has a layered structure, which can also be understood as a sandwich-structure.

According to a non-limiting embodiment, a host material is an inorganic crystalline or polycrystalline material. Typical host materials are oxides, nitrides and oxynitrides, sulfides, selenides, halides or silicates of different elements such as zinc, cadmium, manganese, aluminum, silicon, or various rare-earth metals or combinations thereof. A doped host material is an inorganic crystalline or polycrystalline material that comprises an element, i.e. a dopant, in the crystalline or polycrystalline material. An undoped host material is a host material that does not comprise any dopant, i.e. less than 0.01 at %, such as less than 0.001 at % of the dopant in the host material, or 0 at % of the dopant in the host material. For example, the dopant may be absent from undoped host material.

According to a non-limiting embodiment, a doped host material is a phosphor. A phosphor is a material that converts light of a certain first wavelength to light of a certain second wavelength.

The ceramic wavelength converter assembly comprises two first layers comprising an undoped host material e.g. undoped YAG (yttrium-aluminum-garnet), or a doped host material (e.g. doped YAG). In an embodiment, the first layers may comprise sub-layers, e.g. a first layer may comprise two, three, four or more layers, so-called sub-layers.

In an embodiment, the ceramic wavelength converter assembly with a layered structure comprises the combination of undoped and doped YAG in the first layers and the third layer. In a further embodiment, the ceramic wavelength converter assembly with a layered structure comprises the combination of doped YAG with different doping levels in atomic percent in the first layers and the third layer.

First wavelengths are wavelengths between 300 nm to 570 nm. In an embodiment the first wavelengths are between 350 nm to 500 nm. In a further embodiment the first wavelengths are between 420 nm to 480 nm.

Structures that can produce light of a first wavelength are, e.g., InGaN or GaN chips, or solid state laser diodes.

Second wavelengths are wavelengths between 350 nm nm to 800 nm. In an embodiment the second wavelengths are between 380 nm to 750 nm. In a further embodiment the second wavelengths are between 400 nm to 700 nm. In another embodiment, light of the second wavelength is white light.

In an embodiment the phosphors are inorganic compounds. Non-limiting phosphors are garnets, oxynitridosilicates, perovskites, quantum dots, silicates or combinations thereof, each doped with at least one appropriate element. A non-limiting phosphor is doped garnet, wherein the dopant is Ce.

The phosphors may be doped with different activators, i.e., dopants. Doping in the context of phosphors means the introduction of impurities (dopants) in the crystal structure of the host material. Dopants may be metal ions, such as Ce³⁺, Gd³⁺, Eu²⁺, wherein Ce³⁺ is preferred depending on applications. The amount of dopants in the crystal structure may vary in a broad range. Typical amounts of dopants are 0.01 at % up to 20 at %. The amounts of dopants depend on optical properties of the final product such as color point, thermal quenching, and color temperature etc.

Exemplary doped phosphors are YAG:Ce, YAG:Ce (Gd), LuAG:Ce, LuAG:Ce(Gd), SrSi₂O₂N₂:Eu, SiAlON:Eu etc.

In an embodiment YAG:Ce may be doped with at least 3% of Gd. In alternative embodiments YAG:Ce may be doped with at least 6% of Gd.

In an embodiment, the amount of the dopants in the ceramic wavelength converter assembly is at least 0.8 at %.

In a further embodiment, the difference between the amount of the dopants in the layer(s) with the doped host material and the layer(s) with the undoped host material is at least 0.7 at %.

The third layer can be also understood as central or middle layer of the assembly. The third layer may comprise more than one layer. In an embodiment, the third layer may comprise two, three, four or more layers, so-called sub-layers. The third layer may comprise the undoped host material, or the doped host material.

In an embodiment, one of the first layers and the third layer is doped and the other(s) is/are undoped. In other words, the first layers may comprise doped host materials and the third layer comprises undoped host material. In an aspect of this embodiment, the doped and the undoped host material is derived from the same compound class. E.g. the first and third layers comprise garnet, such as YAG for the undoped host material and YAG:Ce for the doped host material.

In an alternative embodiment, the first layers may comprise undoped host material and the third layer comprises doped host material. In an aspect of this embodiment, the doped and the undoped host material is derived from the same compound class. E.g. the first and third layers comprise garnet compounds, such as YAG for the undoped host material and YAG:Ce (Gd) for the doped host material.

In an alternative embodiment, the first and third layers may both comprise doped host material but with different doping levels. In an aspect of this embodiment, the both doped host materials are derived from the same compound class. E.g. the first and third layers comprise garnet compounds.

Further examples of undoped host material and doped host material pairs are of the same compound class e.g. the two first layers are completely undoped such as YAG, and the third layer is doped with Ce such as YAG:Ce.

In an embodiment the first and/or third layers are made completely out of the host material. In this embodiment, the host material is in the form of a crystal, or in the form of a sintered ceramic material. The sintered ceramic material might further comprise a sinter aid.

In an embodiment the host materials are a mixture of different host materials.

In a further embodiment, the host materials are particles, platelets, or elongated crystals embedded in a matrix material. The matrix material might be oxides. An exemplary embodiment of the matrix material is Al₂O₃.

In an embodiment each of the first layers has a thickness of 0.1 μm to 100 μm. In a non-limiting embodiment each of the first layers has a thickness of 1 μm to 50 μm. In another non-limiting embodiment each of the first layers has a thickness of 3 μm to 40 μm. In an aspect of the embodiment, each of the first layers has the same thickness. In an alternative aspect of the embodiment, each of the first layers has a different thickness.

In an embodiment the third layer has a thickness of 0.1 μm to 100 μm. In a non-limiting embodiment the third layer has a thickness of 1 μm to 50 μm. In another non-limiting embodiment the third layer has a thickness of 3 μm to 30 μm. In an aspect of the embodiment, the third layer comprises more than one layer, wherein each of the layers has the same thickness. In an aspect of the embodiment, the third layer comprises more than one layer, wherein each of the layers has a different thickness.

The ceramic wavelength converter assembly having a layered structure comprises also two second layers comprising a barrier material, and being disposed between the two first layers. In an embodiment, the second layers completely separate the first layers from each other. In a further embodiment, the second layers completely separate the first layers from the third layer.

As described herein, a barrier material, which preferably cannot form a crystal with a dopant, is a material that prevents at least partially or completely the imparting of the dopant from the layer(s) comprising the doped host material to the layer(s) comprising the undoped host materials.

The second layers act as barrier layers. The barrier layers, advantageously prevent completely or at least partially, the imparting of the dopant from the first to the third layers or from the third to the first layers. In an embodiment, the barrier layers comprise the barrier material. In an alternative embodiment, the barrier layers consist of the barrier material.

In an embodiment, the second layers comprise or constitute of a transparent or highly translucent material, i.e. the incoming light can pass through without or nearly without any omission of light. In an embodiment, the second layers comprise or constitute of an inorganic material. In an embodiment, the second layers comprise or constitute of a metal oxide.

Exemplary materials of second layers are Al₂O₃, SiO₂, or MgAl₂O₄ etc.

In an embodiment, the second layers comprise Al₂O₃. In an embodiment, the second layers constitute of Al₂O₃.

In an embodiment, each of the second layers comprise or constitute of the same material. In an alternative embodiment, each of the second layers comprise or constitute of different materials.

In an embodiment, the second layers may comprise sub-layers, e.g. a second layer may comprise two, three, four or more layers, so-called sub-layers.

In an embodiment each of the second layers has a thickness of 0.1 μm to 100 μm. In a non-limiting embodiment each of the second layers has a thickness of 1 μm to 50 μm. In another non-limiting embodiment each of the second layers has a thickness of 3 μm to 20 μm. The thickness is chosen in this way to prevent the diffusion of the dopant from the layer(s) with the doped host material to the layer(s) with the undoped host material.

In an embodiment the ceramic wavelength converter assembly comprises more layers. In an aspect of this embodiment, each of the first layers might comprise 2 layers, 3 layers, 4 layers or even more layers. In an aspect of this embodiment, the first layers are undoped host material layers. In an alternative aspect the first layers are doped host material layers. In a further aspect of this embodiment the first layers each comprise different doped host materials that allow the conversion of light of a certain first wavelength to a second wavelength. With the use of different conversion materials, the adjustment of the color of the emitted light is possible.

In a further embodiment, the third layer of the ceramic wavelength converter assembly comprises 2 layers, 3 layers, 4 layers or even more layers. In an aspect of this embodiment, the third layers are undoped host material layers. In an alternative aspect the third layers are doped host material layers. In a further aspect of this embodiment the third layers each comprise different doped host materials that allow the conversion of light of a certain first wavelength to a second wavelength. With the use of different conversion materials, the adjustment of the color of the emitted light is possible. In an aspect of this embodiment, the ceramic wavelength converter assembly comprises undoped first layers and doped third layers. In an alternative aspect of this embodiment, the ceramic wavelength converter assembly comprises doped first layers and undoped third layers.

According to a non-limiting embodiment, at least one of the two first layers comprise a patterned structure. A patterned structure may be understood as a certain surface morphology, i.e., that the surface shows protrusions and holes in between the protrusions. The patterned structure may improve the coupling of blue light to ceramic wavelength converter assemblies. The blue photon absorption may be significantly increased in a multi-layer ceramic wavelength converter assembly.

Furthermore, a similar pattern on the surface can improve light extraction and thus overall efficiency.

In an embodiment, the patterned structure is a regular patterned, or a non-regular patterned structure. A regular patterned structure may be a surface morphology that follows a certain order, i.e., the protrusions are neighbored to each other in substantially equal or equal distances. A regular patterned structure may be also a surface morphology that shows protrusions of the same form, e.g., all protrusions may be triangles, or all protrusions may be squares, etc. Said protrusions may be arranged in relation to each other with substantially equal or equal distances. A non-regular structure may be a surface morphology that does not follow a certain order, i.e., the protrusions are neighbored to each other in non-equal distances, but in irregular distances. A non-regular patterned structure may be also a surface morphology that shows protrusions of different forms, e.g., one or more protrusions may be triangles and one or more protrusions may be squares. Said protrusions may be arranged to each other with different distances.

In a further embodiment, one of the two first layers comprises a patterned structure. In an alternative embodiment, both first layers comprise a patterned structure. In an alternative embodiment, if more than two first layers are present, all these first layers may be patterned or a certain amount of first layers is patterned.

The patterned structure may comprise at least one structure element selected from a geometric shape. In a cross sectional view, the structure element may be selected from the group consisting of triangle, rectangular, square, parallelogram and trapezoid. The structure element may be arranged in different orientations or in combination.

The structure element may have a certain depth and width and if more than one structure element is present, they may be arranged in a certain distance. Typical depths are between about 20 nm to about 30 μm. Typical widths are between about 20 nm to about 30 μm. Typical distances between the structure elements are between about 20 nm to about 100 μm.

In an exemplary embodiment, the structure element has a triangle shape. The triangle may have a depth from about 20 nm to about 30 μm. Typical depths may be about 20 nm, about 200 nm, about 400 nm, about 800 nm, about 1 μm, about 4 μm, about 8 μm, about 12 μm, or about 30 μm. Non-limiting depths are between about 8 μm to about 16 μm, e.g., about 8 μm, 12 μm, or about 16 μm.

In a non-limiting embodiment, the depth of the structure element is less than the thickness of the first layer. The triangle may have a width from about 20 nm to about 30 μm. Typical widths may be about 20 nm, about 200 nm, about 400 nm, about 800 nm, about 1 μm, about 4 μm, about 8 μm, about 12 μm, about 30 μm, or any other numbers. Non-limiting widths are between about 8 μm to about 16 μm, e.g., about 8 μm, 12 μm, about 16 μm, or other numbers. If more than one structure element is present, they may be arranged apart from each other with a certain distance. Typical distances between triangle structure elements may be from about 20 nm to about 100 μm. Typical distances may be about 20 nm, about 200 nm, about 400 nm, about 800 nm, about 1 μm, about 4 μm, about 8 μm, about 12 μm, about 100 μm, or other numbers. Non-limiting distances between triangle structure elements are from about 10 μm to about 50 μm, e.g., about 10 μm, about 20 μm, about 30 μm, about 40 μm, or about 50 μm.

In an exemplary embodiment, the structure element has a truncated shape. The truncated shape may have a depth from about 20 nm to about 30 μm. Typical depths may be about 20 nm, about 200 nm, about 400 nm, about 800 nm, about 1 μm, about 4 μm, about 8 μm, about 12 μm, about 30 μm, or other numbers.

Non-limiting depths are between about 2 μm to about 16 μm, e.g., about 2 μm, about 8 μm, 12 μm, or about 16 μm. In a non-limiting embodiment, the depth of the structure element is less than the thickness of the first layer. The truncated shape may have a top dimension with side lengths from about 1×1 nm to about 12×12 μm. Typical top dimensions with side lengths may be about 1×1 nm, about 10×10 nm, about 100×100 nm, about 200×200 nm, about 400×400 nm, about 2×2 μm, about 8×8 μm, about 12×12 μm, about 20×20 μm, or any other numbers. Non-limiting top dimensions with side lengths of the truncated shape are between about 200×200 nm to about 12×12 μm, e.g., about 200×200 nm, 1000×1000 nm, about 2×2 μm about 8×8 μm about 12×12 μm, or other numbers.

The truncated shape may have a bottom dimension with side lengths from about 10×10 nm to about 20×20 μm. Typical bottom dimensions with side lengths may be about 10×10 nm, about 100×100 nm, about 200×200 nm, about 400×400 nm, about 2×2 μm, about 8×8 μm, about 12×12 μm, about 20×20 μm, or any other numbers. Non-limiting bottom dimensions with side lengths of the truncated shape are between about 2×2 μm to about 20×20 μm, e.g., about 2×2 μm, about 8×8 μm, about 10×10 μm, about 20×20 μm, or other numbers. If more than one structure element is present, they may be arranged apart from each other with a certain distance. Typical distances between truncated structure elements may be from about 20 nm to about 50 μm. Typical distances may be about 20 nm, about 100 nm, about 200 nm, about 800 nm, about 1 μm, about 5 μm, about 30 μm, about 40 μm, about 50 μm, or other numbers. Non-limiting distances between triangle structure elements are from about 10 μm to about 50 μm, e.g., about 10 μm, about 20 μm, about 30 μm, about 40 μm, or about 50 μm.

The structure elements may be present in certain areas of the first layer. In an embodiment, they may cover the whole outer surface of the first layer. In an alternative embodiment, they may cover a part of the outer surface of the first layer, e.g., they may cover 80%, 70%, 50%, 30%, or 20% of the outer surface of the first layer. In a non-limiting, the outer surface of the first layer is defined as the surface being opposite to the second layer.

From a top view perspective, the structure elements may form a certain geometric pattern on the first layer. Thus, the structure elements may form a pentagon, a hexagon, a heptagon, an octagon, a circle, a square, or any other geometric patterns.

A further object is a light emitting device comprising: a light-emitting structure configured to emit a primary light having a first peak wavelength, and a ceramic wavelength converter assembly positioned to receive the primary light from the light-emitting structure, the ceramic wavelength converter assembly comprising: two first layers comprising an undoped host material, or a doped host material, two second layers comprising a barrier material and being disposed between the two first layers, and a third layer comprising a doped host material, or an undoped host material and being disposed between the two second layers, wherein the two first layers comprise the undoped host material and the third layer comprises the doped host material, or wherein the two first layers comprise the doped host material and the third layer comprises the undoped host material, wherein at least one of the two first layers comprise a patterned structure.

A light emitting structure is an element that emits primary light with a certain wavelength. The light emitting structure might be a radiation-emitting semiconductor chip emitting primary radiation from a radiation exit area during operation. The semiconductor chip might be a light-emitting diode.

The light-emitting structure, the ceramic wavelength converter assembly, the first layers, the second layers and the third layer, the barrier material, the patterned structure as well as the phosphor material may correspond to the respective means and materials as described above.

In an embodiment, the barrier material of the light emitting device is selected from the group consisting of Al₂O₃, SiO₂, MgAl₂O₄, and combinations thereof. In a non-limiting embodiment, the barrier material of the light emitting device is Al₂O₃.

In an embodiment, the phosphor of the light emitting device is selected from the group consisting of garnet, LuAG:Ce (Gd) etc. In a non-limiting embodiment, the phosphor of the light emitting device is YAG:Ce.

In a further embodiment of the light emitting device, the first layers are undoped YAG. In a further embodiment of the light emitting device the doped host material is YAG:Ce.

In an embodiment of the light emitting device, the first layers consist of YAG. In a further embodiment of the light emitting device, the first layers consist of YAG:Ce.

In an embodiment of the light emitting device, the third layer consists of YAG. In a further embodiment of the light emitting device, the third layer consists of YAG:Ce.

In an embodiment of the light emitting device, the first layers consist of undoped host material (e.g. YAG) and the third layer consists of doped host material (e.g. YAG:Ce). In an alternative embodiment of the light emitting device, the first layers consist of doped host material (e.g. YAG:Ce) and the third layer consists of undoped host material (e.g. YAG). In an aspect of these embodiments, the second layers acting as barrier layers consist of a metal oxide (e.g. Al₂O₃).

In some embodiments the light emitting devices are coated with at least one layer of SiO₂, Al₂O₃, or a combination thereof.

In an embodiment, the at least one of the first layers comprising the patterned structure is placed in close proximity to the light-emitting structure.

According to the present disclosure, “in close proximity with” may be defined as “in direct contact with”. In other words, the one of the first layers comprising the patterned surface may be in direct contact to the light-emitting structure. In an alternative embodiment, “in close proximity” may also be understood, as being separated by a minimal layer, e.g., a layer being less than 10 μm such as a an adhesive layer or the like.

In an alternative embodiment, the at least one of the first layers comprising the patterned structure is placed in the most furthest way spaced apart from the light-emitting structure.

In an embodiment, both of the two first layers comprise the patterned structure, as described herein.

In a further embodiment, the patterned structure is a regular patterned structure, or a non-regular patterned structure, as described herein.

The patterned structure of the light emitting device might be selected from a specific pattern. the patterned structure might comprise at least one structure element selected from the group consisting of triangle, rectangular, square, parallelogram, trapezoid, or a combination thereof.

The patterned structure might also be arranged on the at least one first layer as described herein, e.g., in a pentagon, hexagon, heptagon, octagon, circle, or a combination thereof.

In an embodiment, the doped host material of the light emitting device is a phosphor, such as a phosphor as described herein.

If a glue layer is present in a light emitting device, such as between the wavelength converter and the light emitting structure, the patterned structure might be adapted to have an improved wetting behavior and thus, such as improved the blue photon coupling effect and adhesive forces between the connected parts.

The ceramic wavelength converter assembly might be useful in any light emitting device known to the person skilled in the art. The light emitting devices comprising the ceramic wavelength converter assemblies, or light emitting devices are useful in various applications. Exemplary applications of the light emitting devices are in automotive industry, in household appliances, in general lighting.

A further object is a method for producing a ceramic wavelength converter assembly having a layered structure that includes two first layers, two second layers and a third layer, the method comprising: providing a third layer comprising a doped host material or an undoped host material, applying a second layer comprising a barrier material on an upper side of the third layer and applying a second layer comprising a barrier material on a lower side of the third layer, applying first layers comprising an undoped host material, or a doped host material on each of the sides of the second layers opposite to the sides being in contact with the third layer, and patterning at least one of the two first layers, wherein the two first layers comprise the undoped host material and the third layer comprises the doped host material, or wherein the two first layers comprise the doped host material and the third layer comprises the undoped host material.

In an alternative embodiment, a method for producing a ceramic wavelength converter assembly having a layered structure that includes top and bottom first layers, top and bottom second layers, and a third layer is described. The method comprises forming the bottom second layer on an upper side of the bottom first layer; forming the third layer on an upper side of the bottom second layer; forming the top second layer on an upper side of the third layer; and forming the top first layer on an upper side of the top second layer and patterning at least one of the two first layers. The top and bottom second layers comprise barrier layers. The top and bottom first layers comprise an undoped host material and the third layer comprises a doped host material, or the top and bottom first layers comprise the doped host material and the third layer comprises the undoped host material.

The ceramic wavelength converter, the first layers, the second layers and the third layer, the barrier material as well as the host materials may correspond to the respective means and materials as described above. Also the patterned structure might correspond to the patterned structures as described herein.

The application of the layers may be carried out by a conventional tape cast process consisting of the procedures like tape-casting, blanking, lamination, punch etc. processes.

In an embodiment, the doped host material of the method might be a phosphor, as disclosed herein.

The patterning of the at least one first layer might be carried out by conventional processes known in the art. In an embodiment, the patterning is made by chemical etching, sandblasting, dicing, laser machining, laser ablation, laser scribing, or a combination thereof. The patterning might be selected depending on the material of the first layer and the desired structural element of the pattern.

Further methods may be photolithographic techniques combining a mask and selective etching, a dicing blade, imprinting the pattern of the ceramic while still in the green state (before sintering applied or before hardened) or, in the case of non-periodic patterns, sand blast can be used to randomly roughen the surface.

When random patterns are desired, techniques based on chemical etching and sandblasting could be employed. For regular patterning processes such as dicing or laser machining are possible options.

Laser scribing can be performed on either green body (i.e. before sintering applied), or biscuit-sintered body (not fully sintered but with a reasonable strength for handling) or even fully-sintered ceramic body. Different materials can show a different response to the laser depending on their absorbance and the laser parameters used. In an embodiment, all the samples with and without patterning are sintered under the same conditions after the pattern had been written on them. This is also likely to change the actual dimensions of the pattern from the target values as samples may shrink during sintering.

The ceramic wavelength converter assembly may be used in a light emitting device.

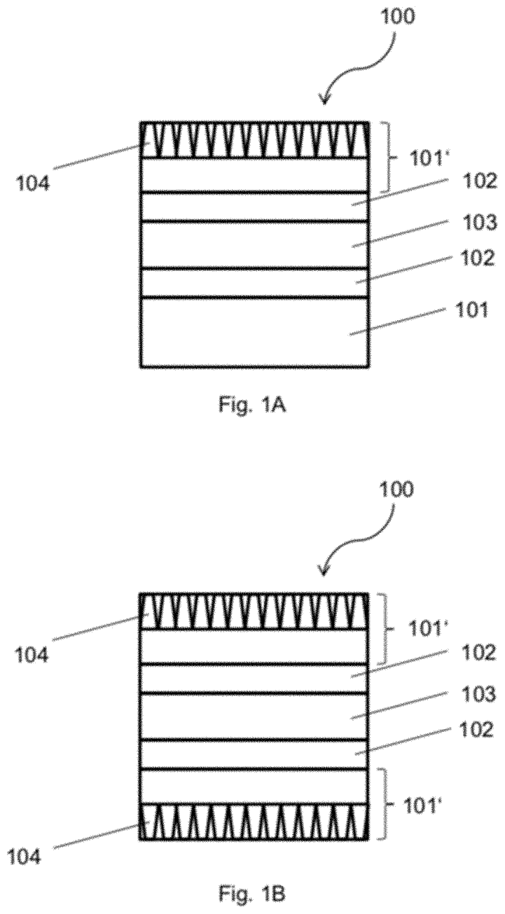

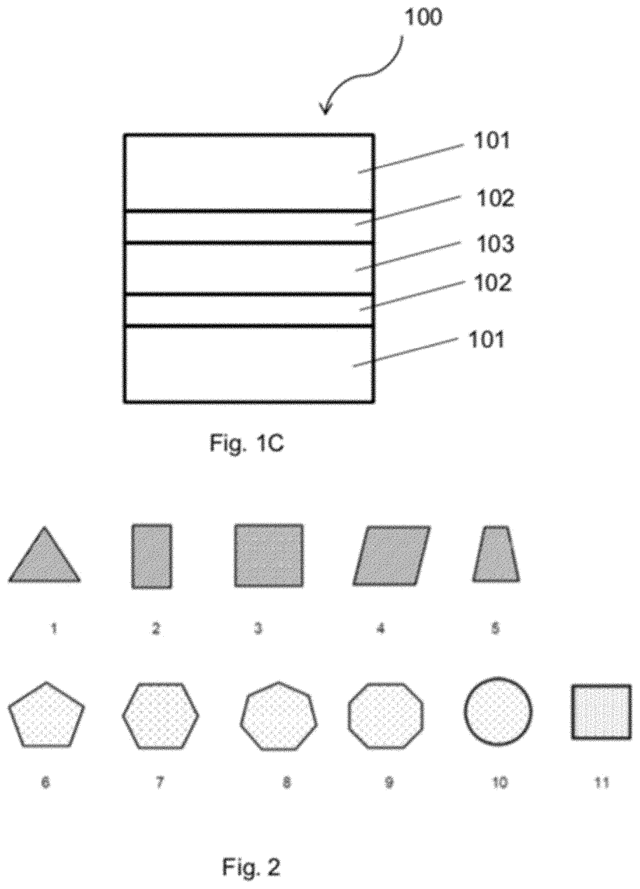

FIG. 1A shows a schematic drawing of a layered ceramic wavelength converter assembly 100 with a first layer 101, a first layer 101′ with a patterned structure 104, two second layers 102, and a third layer 103.

FIG. 1B shows a schematic drawing of a layered ceramic wavelength converter assembly 100 with two first layers 101′ with a patterned structure 104, two second layers 102, and a third layer 103. The patterned structures 104 may have the same structural element or may have different structural elements.

FIG. 1C shows a schematic drawing of a layered ceramic wavelength converter assembly 100 with two first layers 101, a second layer 102 and a third layer 103 according to the state of the art.

The ceramic converter assembly 100 may have a thickness of 30 μm to 300 μm, such as from 40 μm to 250 μm, or from 50 μm to 250 μm. The ceramic converter assembly 100 has a platen-like shape, although it is not limited to that. The ceramic converter assembly 100 of FIG. 1A shows the layered structure, which can also be characterized as sandwich structure.

The ceramic converter assembly 100 comprises two first layers 101 and 101′ in FIG. 1A, two first layers 101′ in FIG. 1B and two first layers 101 in FIG. 1C, of an undoped YAG. The thickness of the first layers 101 and 101′ is about 35 μm. In the center of the ceramic converter assembly 100 is a Ce-doped YAG third layer 103. The thickness of the third layer 103 is about 14 μm. The third layer 103 may also be doped with 0.1 at % to 20 at % of Gd. The ceramic converter assembly 100 further comprises two second layers 102, which act as barrier layers. The second layers 102 each have a thickness of about 12 μm. In a non-limiting embodiment the second layers 102 have a thickness of 3 μm to 10 μm. Due to the small thickness of the second layers 102, undesirable or excessive scattering can be avoided.

The thickness of the second layers 102 is chosen as to just eliminate the diffusion of the dopant from the doped layer(s) to the undoped layer(s).

Therefore a high forward transmission at a desirable level can also be obtained.

The second layers 102 may consist of Al₂O₃. In a non-limiting embodiment, the second layers 102 completely separate the third layer 103 from the first layers 101. In a further embodiment, the third layer 103 is the undoped YAG layer and the first layers 101, and 101′, respectively, are the doped YAG (either doped with Ce³⁺ or Gd³⁺ or their combination layers).

The configuration which is presented in FIGS. 1A, 1B and 1C allows reduced Gd doping or even completely eliminating Gd doping which imparts the materials with excellent thermal quenching at elevated temperatures (e.g. about 4% higher in brightness at 110° C. than YAG:Ce doped with 15% Gd). The thin Al₂O₃ layers serving as barrier layers to prevent Ce diffusion from the central YAG:Ce layer to the undoped YAG layers at sintering temperatures to keep the color steering simplified, while at the same time to improve the thermal conductivity, and allow the undoped YAG layers to achieve a high transparency with least scattering. By combination of different thicknesses of the different layers, the scattering behavior of the sandwich structured ceramic materials can be tailored to the desirable level which generates the highest brightness at both room and elevated temperatures. Therefore the ceramic converter assembly improves the brightness at both room temperature (25° C.) and elevated temperature (e.g. up to 150° C.), and even provides a solution to applications at high power intensity where high flux/power intensity applied.

The separation of the third layer 103 from the two first layers 101, or 101′, respectively, allows the complete elimination of doping from the layer with the doped host material to the layer with the undoped host material. In exemplary embodiments with YAG:Ce(Gd) as doped host material, the layer with the doped host material can be reduced in thickness. In these embodiments the total thickness of the ceramic wavelength converter assembly can be made up by the adjustment of the combinations of the second layers and the layer(s) with the undoped host material if necessary. These exemplary embodiments can be made with a conventional tape cast process.

The complete elimination of the Gd³⁺ doping, either in the first layers 101, or 101′, respectively, or third layer 103 will also impart the highest thermal quenching performance of the materials at elevated temperatures, even at 150° C. The application of second layers 102 not only serves as a barrier layer to prevent the dopant diffusion from the layer(s) with the doped host material to the layer(s) with the undoped host material. The introduction of the second layers 102 can also improve the thermal conductivity of the ceramic converter assembly, hence improve the thermal performance. The application of both second layers 102 and layer(s) with undoped host material not only offers the means to adjust the thickness of the total thickness of the sandwich ceramic converter assembly but also provide the means to tailor the scattering of the sandwich parts for the highest brightness with engineered forward scattering.

The sandwich-like structured ceramic converter currently offers a cost effective way, which is comparable to the current large scale production method.

The patterned structure 104, which is either present in one of the first layers 101 (FIG. 1A), or in both of the first layers 101′ (FIG. 1B) are responsible for blue photon improvements compared to first layers 101 without any patterned structure 104 (FIG. 1C).

FIG. 2 shows different structure elements of the pattern. Whereas nos. 1 to 5 represent cross-section profiles of the structure elements, nos. 6 to 11 represent top views of the arrangement of the patterns on the first layer. The following structure elements are presented: triangle (1), rectangular (2), square (3), parallelogram (4), trapezoid (5), pentagon (6), hexagon (7), heptagon (8), octagon (9), circle (10) and square (11).

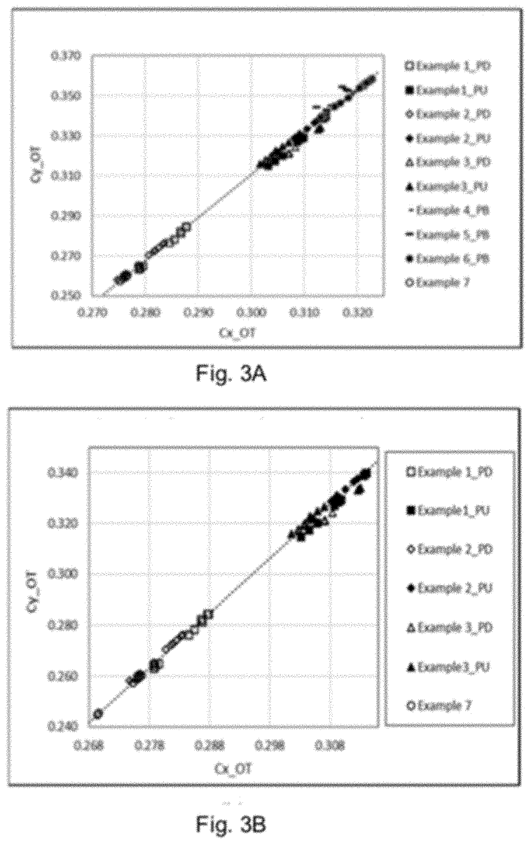

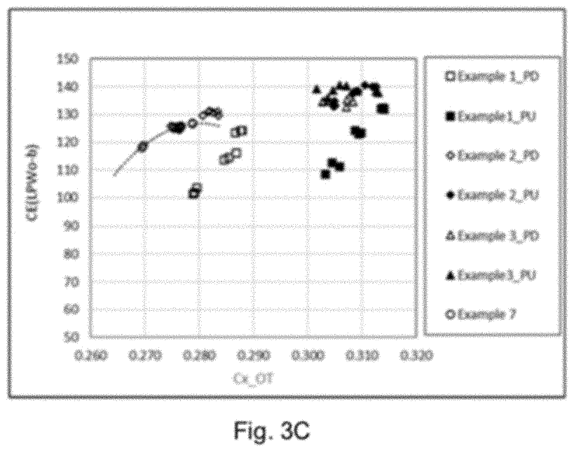

FIG. 3 shows the conversion line, the relationship between the color point and the conversion efficiency of different patterning conditions of exemplary embodiments as described in the Examples. FIG. 3A shows the conversion line for all examples. FIG. 3B shows the conversion line of examples with first layers without a pattern (Example 7) and examples, wherein one of the first layers is patterned. FIG. 3C shows the conversion efficiency of examples with first layers without a pattern (Example 7) and examples, wherein one of the first layers is patterned. In FIG. 3, examples 1 through 6, PD and PU represent one side patterned of the first layers and tested in the mode patterned side down (PD) and patterned side up (PU), respectively; PB represent both sides of the first layers are patterned.

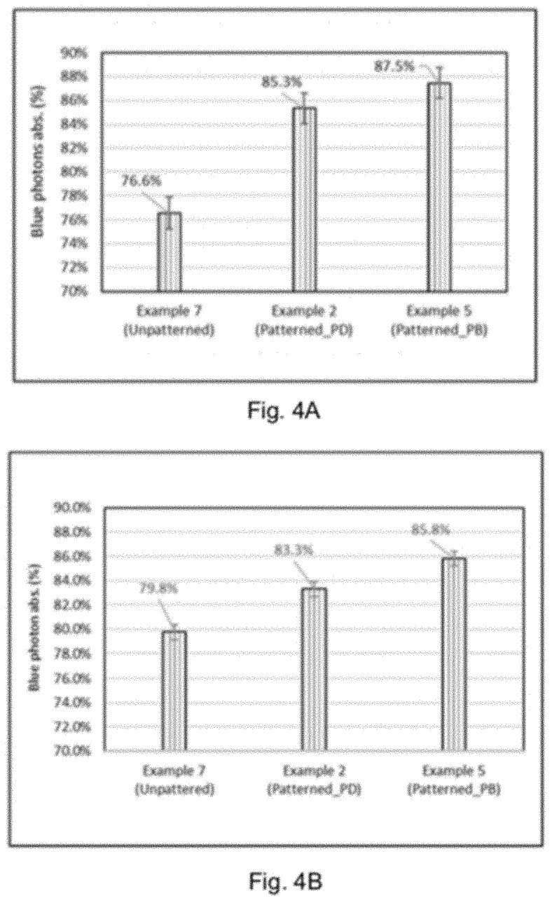

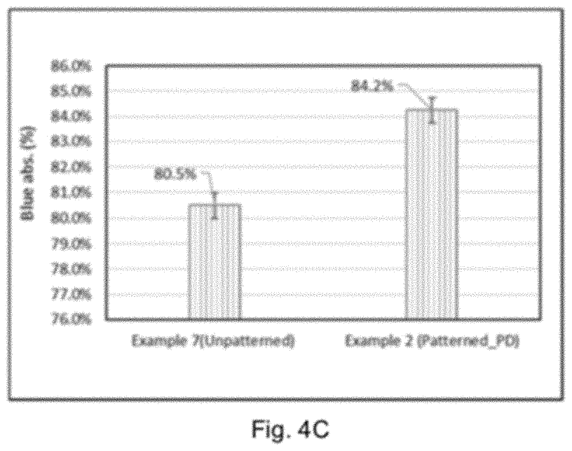

FIG. 4 shows the blue photon absorptions for samples with and without surface patterning and tested under different conditions. FIG. 4A shows the blue photon absorptions for samples tested on a chip as light emitting structure only without glue. FIG. 4B shows the blue photon absorptions for samples glued to the chip and FIG. 4C shows the blue photon absorptions for samples glued to the chip and with a TiO₂ cast. Throughout the figures it can be seen that the blue photon absorption is improved for those samples that comprise a patterned surface.

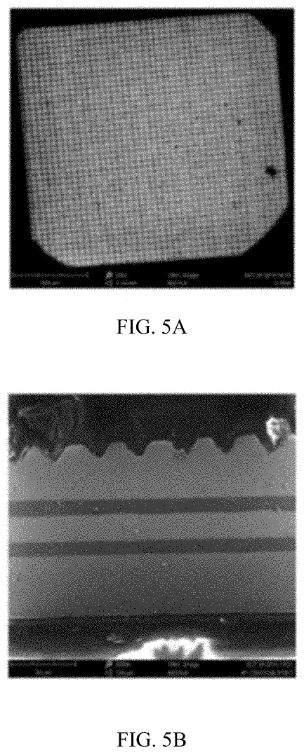

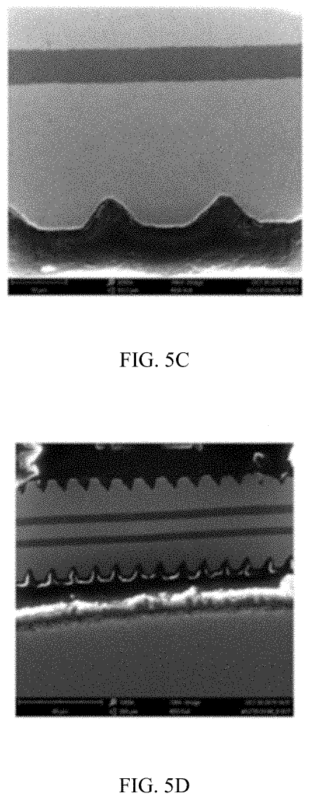

FIGS. 5A-5C show SEM images presenting the surface patterning profiles of ceramic wavelength converter assemblies, in which one of the first layers is patterned, or both first layers are patterned. FIG. 5A shows a general surface profile of patterned surface from the top. FIG. 5B is a cross-section of a ceramic wavelength converter assembly, wherein one first layer is patterned and one first layer is unpatterned. FIG. 5C is a close-up view of a pattered layer. FIG. 5D is a cross section view of a ceramic wavelength converter assembly, wherein both first layers are patterned.

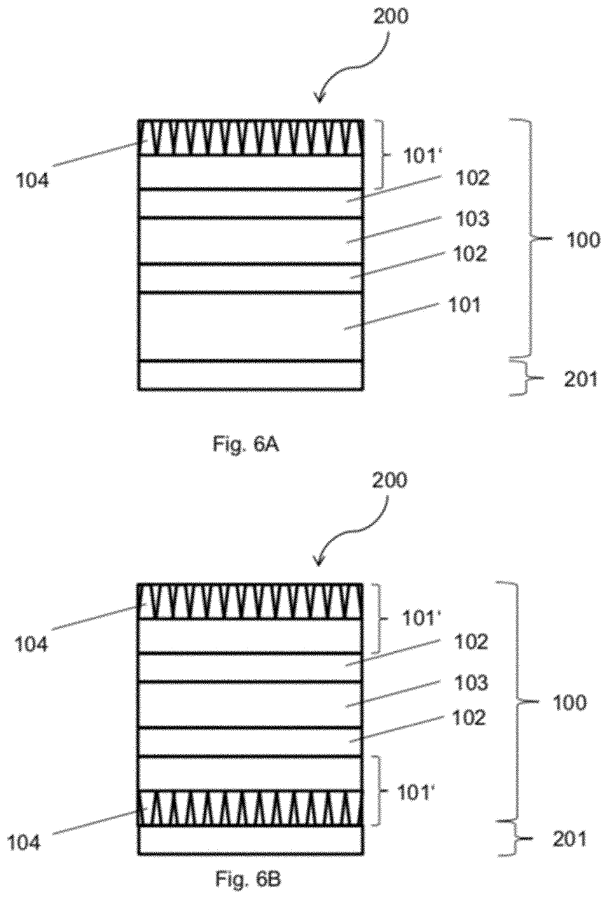

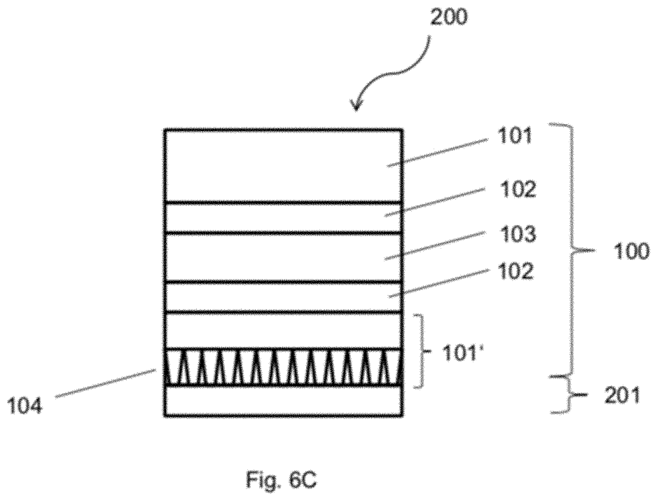

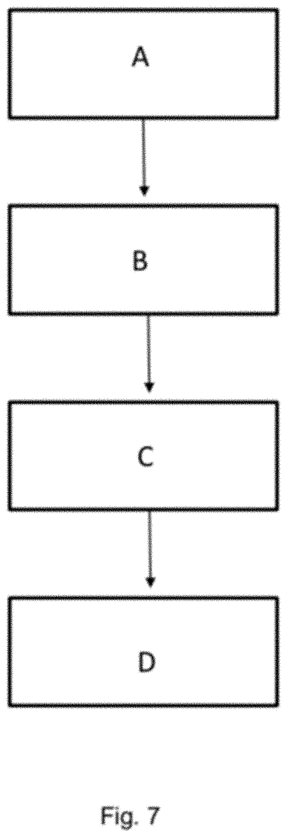

FIGS. 6A-6B show exemplary embodiments of light emitting devices 200. FIG. 6A shows an embodiment, wherein the ceramic wavelength converter 100 is attached to the light-emitting structure 201, e.g., with a glue. The ceramic wavelength converter assembly 100 comprises a first layer 101, a first layer with a patterned structure 101′, two second layers 102 and a third layer 103. The patterned structure 104 is positioned on the far most to the light-emitting structure 201.

FIG. 6B shows an embodiment, wherein the ceramic wavelength converter 100 is attached to the light-emitting structure 201, e.g., with a glue. The ceramic wavelength converter assembly 100 comprises two first layers 101′, two second layers 102 and a third layer 103. The patterned structure 104 is present in both first layers, wherein the patterned structure 104 might be the same in both first layers 101′, or might be different. The patterned structure 104 is positioned in one of the first layers 101′ in close proximity to the light-emitting structure 201.

FIG. 6C shows an embodiment, wherein the ceramic wavelength converter 100 is attached to the light-emitting structure 201, e.g., with a glue. The ceramic wavelength converter assembly 100 comprises a first layer 101, a first layer 101′, two second layers 102 and a third layer 103. The patterned structure 104 is positioned in close proximity to the light-emitting structure 201.

The dimensions of each of the layer in FIG. 6 might correspond to the dimensions as described for the embodiments of FIG. 1.

FIG. 7 shows a schematic overview of a method for producing a ceramic wavelength converter assembly having a layered structure that includes two first layers, two second layers and a third layer. In A, the third layer comprising a doped host material or an undoped host material is provided. In B, the second layer is applied on an upper side of the third layer and the second layer is applied on a lower side of the third layer where the second layer includes a barrier material. In C, the first layer is applied on a side of the second layers furthest from the third layer where the first layers include an undoped host material or a doped host material. In D, at least one of the first layers is patterned by a procedure described herein. In an embodiment, the two first layers may include the undoped host material and the third layer may include the doped host material, or in an alternative embodiment, the two first layers may include the doped host material and the third layer may include the undoped host material.

### EXAMPLES

Starting powders as disclosed in U.S. Pat. No. 10,873,009 B2:

YAG:Ce phosphor (for central layer, i.e., third layer).

YAG:Ce (Gd) phosphor for central layer can be obtained in two ways as below:

Pre-synthesized before sintering.

Phase: cubic crystal phase >95% (or less than 5 vol. % if any Gd-rich phase present).

Ce doping level: 0.1%-6%, such as level 0.1%-4%.

Particle size: d₅₀ 0.01 μm-50 μm, and d₉₀≤30 μm, such as d₅₀ ca. 0.1 μm-20 μm and d₉₀≤25 μm.

Sinterability: highly active and sinterable.

YAG powders (for undoped layer).

Phase: with cubic purity >99.5% Particle size: d₅₀ 0.01 μm-10 μm, and d₉₀≤20 μm, such as d₅₀ ca. 0.01 μm-1 μm and d₉₀≤5 μm.

Sinterability: highly active and sinterable.

In-situ synthesized during sintering by mixed-oxide approach.

Oxides such as Y₂O₃, Al₂O₃, CeO₂, and Gd₂O₃ (if any) were weighed in the weight proportion according to the YAG:Ce (Gd if any) formulation as desired; e.g., (YₓGd_{y}Ce_{(1-x-y)})₃Al₅O₁₂, where x+y<1; 0.7≤x<1; 0≤y<0.3,

Al₂O₃ powders (for barrier layer, i.e. second layers).

Phase: Al₂O₃ with no second phase, >99.5 wt % pure.

Particle size: d₅₀ 0.01 μm-5 μm, and d₉₀≤10 μm, such as d₅₀ ca. 0.01 μm-1 μm and d₉₀≤3 μm.

Sinterability: highly active and sinterable.

Y₂O₃ powders (for undoped layer).

Phase: Y₂O₃ with no detectable second phase, >99.5 wt % pure.

Particle size: d₅₀ 0.01 μm-5 μm, and d₉₀≤10 μm, such as d₅₀ ca. 0.01 μm-1 μm and d₉₀≤3 μm.

Sinterability: highly active and sinterable.

In an embodiment, the sandwich-like structured ceramic wavelength converter assembly consists of five layers with three main components as described above. In the final materials after sintering the layer thickness were controlled as below:

YAG:Ce phosphor central or middle layer with or without Gd, thickness ranges from 1 μm to 100 μm, such as from 3 μm to 50 μm, or from 5 μm to 40 μm.

Thin Al₂O₃ barrier layers, which cover the both sides of the central YAG:Ce phosphor layer. The thickness of Al₂O₃ barrier layer ranges from 0.1 μm to 50 μm, such as from 2 μm to 40 μm, or from 4 μm to 20 μm.

Undoped YAG layers, the outmost two layers—undoped transparent YAG layers. The thickness ranges from 0.5 μm to 200 μm, such as from 2 μm to 100 μm, or from 10 μm to 50 μm.

The ceramic wavelength converter assembly can be made by various conventions process, such as die pressing, cold isostatic pressing (CIP), tape cast, hot pressing (HP), hot isostatic pressing (HIP) etc. as forming and/or sintering processes.

However a non-limiting forming process is by conventional tape casting, i.e. by laminating the different layers of different compositions and thickness as designed followed by the punching, prefiring, and sintering. The desired shape for a sintered ceramic wavelength converter assembly may be typically about 1 mm×1 mm square with a thickness of 30 to 2000 microns. The size could be as small as 0.5 mm square for smaller light emitting devices.

Densification can be achieved by either SPS, pressureless sintering (PLS) or other sintering methods such as HIP or GPS etc. The non-limiting sintering technique selected is pressureless sintering. The main characteristic of pressureless sintering (PLS) is its simplicity which easily allows a large scale production to be implemented.

In an embodiment, the ceramic wavelength converter assembly is placed on an alumina setter/plate which is then placed in an air atmosphere furnace and heated using a typical time-temperature cycle of:

25° C. to 400° C. in 4 hours

400° C. to 1150° C. in 4 hours

Hold at 1150° C. for a period of from 0.5 to 2 hours

Cool to 25° C. in 3 hours.

This thermal process removes all of the organic and carbonaceous species including the organic binders used to hold the powders together as well as the pore-forming additive materials if any added according to product requirements. The hold temperature at 1150° C. is also high enough to allow the powder particles to stick together giving the parts sufficient strength to be handled for downstream process. The pore-forming additives are burnt out leaving voids that replicate their sizes and shapes. The pre-fired ceramic plates are transferred onto molybdenum plates and are sintered in a reducing atmosphere such H₂, H₂/N₂, CO, or mixtures thereof are either in dry or in controlled wet, sintered at 1500-1825° C. for a period of from 1 minute to 4 hours at peak temperature. During the sintering, the ceramic parts or platelets shrink as the ceramic powders sinter and the matrix porosity is removed. If the initial powder particle sizes and mixing/milling conditions are performed properly and no pore-forming additives are added to the batch, the porosity of sandwich structured ceramic converter materials will be reduced at elevated sintering temperatures to a level that the part exhibits a high degree of transparency or translucency.

Patterning

When random patterns are desired, techniques based on chemical etching and sandblasting could be employed. For regular patterning the processes like such as dicing or laser machining are possible options. For the samples shown in the examples below, laser machining was performed. Three different configurations with different scribe depths and fixed laser spot size and pattern pitch (Table 1) were used. This method generated motives with a trapezoidal cross-section and square top-view shape:

TABLE 1
Target values used for laser scribing for the examples

| Parameter | Set 1 | Set 2 | Set 3 | Laser scribe |
|---|---|---|---|---|
| Laser spot size | 10 | 10 | 10 | One and/or |
| (μm) | | | | both sides |
| Scribe depth | 10 | 15 | 20 | One and/or |
| (μm) | | | | both sides |
| Pitch (μm) | 30 | 30 | 30 | One and/or |
| | | | | both sides |

Laser scribing can be performed on either green body (i.e. before sintering), or biscuit-sintered body (not fully sintered but with a reasonable strength for handling) or even fully-sintered ceramic body. Different materials can show a different response to the laser depending on their absorbance and the laser parameters used. All the exemplary samples with and without patterning are sintered under the same conditions after the pattern had been written on them. This is also likely to change the actual dimensions of the pattern from the target values as samples may shrink during sintering.

Below are several examples showing the incident blue photon absorption improvements achieved after surface pattering compared to nonpatterned layer structured ceramic converters.

### Examples 1-3

Following the process mentioned above, layer structured sandwich ceramic converters with one side surface patterned were prepared. The parts were sintered at 1690° for 1 hr in wet H₂ and N₂ mixture atmosphere. The structure of the sandwich detail is given schematically in FIG. 6a and thickness of each layer and total thickness are summarized in Table 2. Optical properties such as incident blue photons absorption, conversion quantum efficiency (CQE), chromaticity and lumens per optical blue watt etc. were summarized in Table 3, and the comparison between samples with and without surface patterning were made and illustrated in FIGS. 3 and 4.

TABLE 2

| | | | | | | | Pattern | |
|---|---|---|---|---|---|---|---|---|
| | Total | YAG | Al₂O₃ | YAG:Ce | Patterned | Pattern | top side | Pattern |
| | thickness | layer | layer | layer | side | pitch | length | depth |
| Example | (μm) | (μm) | (μm) | (μm) | condition | (μm) | (μm) | (μm) |
| Example 1 | 82 | 28.5 | 6.5 | 12.0 | 1-side | 20.5 | 7.0 | 6.5 |
| Example 2 | 82 | 28.5 | 6.5 | 12.0 | 1-side | 21.4 | 6.9 | 9.8 |
| Example 3 | 82 | 28.5 | 6.5 | 12.0 | 1-side | 22.2 | 6.8 | 14.5 |
| Example 4 | 82 | 28.5 | 6.5 | 12.0 | 2-side | 20.5 | 7.0 | 6.5 |
| Example 5 | 82 | 28.5 | 6.5 | 12.0 | 2-side | 21.4 | 6.9 | 9.8 |
| Example 6 | 82 | 28.5 | 6.5 | 12.0 | 2-side | 22.2 | 6.8 | 14.5 |
| Example 7 | 82 | 28.5 | 6.5 | 12.0 | unpatterned | N/A | N/A | N/A |
| | | | | | reference | | | |

TABLE 3

| | Pattern | | | | | | | |
|---|---|---|---|---|---|---|---|---|
| | condition & | Part/chip test | Data | | | LPWo- | Blue | |
| Example | test mode | condition | Item * | Cx | Cy | b | Abs. | CQE |
| Example 7 | Unpatterned | Part on chip, | Avg | 0.2920 | 0.2871 | 179.4 | 76.6% | 60.0% |
| | reference | no glue, no | Stdev. | 0.0027 | 0.0063 | 3.1 | 0.5% | 0.8% |
| | | cast | | | | | | |
| Example 2 | One side | Part on chip, | Avg. | 0.3316 | 0.3669 | 200.0 | 85.3% | 61.1% |
| | patterned (PD) | no glue, no | Stdev. | 0.0060 | 0.0120 | 2.9 | 1.3% | 0.2% |
| | | cast | | | | | | |
| Example 5 | Two-side | Part on chip, | Avg. | 0.3439 | 0.3931 | 213.1 | 87.5% | 64.2% |
| | patterned | no glue, no | Stdev. | 0.0024 | 0.0052 | 3.7 | 0.3% | 0.7% |
| | | cast | | | | | | |
| Example 7 | Unpatterned | Part glued to | Avg. | 0.3139 | 0.3322 | 206.3 | 79.8% | 69.4% |
| | reference | chip | Stdev. | 0.0004 | 0.0007 | 0.4 | 0.2% | 0.3% |
| Example 2 | One side | Part glued to | Avg. | 0.3304 | 0.3664 | 220.8 | 83.3% | 71.5% |
| | patterned (PD) | chip | Stdev. | 0.0018 | 0.0041 | 1.5 | 0.4% | 0.3% |
| Example 5 | Two-side | Part glued to | Avg. | 0.3425 | 0.3916 | 227.7 | 85.8% | 72.1% |
| | patterned | chip | Stdev. | 0.0027 | 0.0059 | 3.4 | 0.6% | 1.4% |
| Example 7 | Unpatterned | Part glued | Avg. | 0.3236 | 0.3484 | 225.2 | 80.5% | 75.3% |
| | reference | and cast to | Stdev. | 0.0004 | 0.0013 | 1.3 | 0.2% | 0.7% |
| | | chip | | | | | | |
| Example 2 | One side | Part glued | Avg. | 0.3415 | 0.3858 | 245.3 | 84.2% | 78.8% |
| | patterned (PD) | and cast to | Stdev. | 0.0016 | 0.0039 | 1.1 | 0.4% | 0.3% |
| | | chip | | | | | | |

* Avg.—average of 3 to 5 data collected for each test; Stdev.—standard deviation of 3 to 5 data for each test; PD = one-side patterned and patterned side face down (to the chip) when tested; PU = one-side patterned and patterned side face up when tested; PB = both side patterned and with the same pattern on both sides.

### Examples 4-6

Following the process mentioned above, layer structured sandwich ceramic converters with both side surface patterned were prepared. The parts were sintered under the same condition as in Examples 1-3, i.e. 1690° for 1 hr in wet H₂ and N₂ mixture atmosphere. The structure of the sandwich detail and patterning profile is given schematically in FIG. 1b and thickness of each layer and total thickness are summarized in Table 2; and optical properties such as incident blue photons absorption, conversion quantum efficiency (CQE), chromaticity and lumens per optical blue watt etc. were summarized in Table 3, and the comparison of surface with and without patterns were made and illustrated in FIGS. 3 and 4.

### Example 7 (Reference)

Following the process mentioned above, layer structured sandwich ceramic converters without surface patterning were made as well for reference. The parts were sintered at 1690° C. for 1 hr in wet H₂ and N₂ mixture atmosphere. The structure of the sandwich detail is given FIG. 1c and thickness of each layer and total thickness are summarized in Table 2, and optical properties such as incident blue photons absorption, conversion quantum efficiency (CQE), chromaticity and lumens per optical blue watt etc. were summarized in Table 3, and the comparison of surface without and with different patterns were made and illustrated in FIG. 1.

While there have been shown and described what are at present considered to be preferred embodiments of the invention, it will be apparent to those skilled in the art that various changes and modifications can be made herein without departing from the scope of the invention as defined by the appended claims. The disclosure rather comprises any new feature as well as any combination of features, which in particular includes any combination of features in the appended claims, even if the feature or combination is not per se explicitly indicated in the claims or the examples.

### REFERENCE SIGNS

100 ceramic wavelength converter assembly
101 first layer
101′ first layer with patterned structure
102 second layer
103 third layer
104 patterned structure
200 light emitting device
201 light-emitting structure

What is claimed is:

1. A ceramic wavelength converter assembly having a layered structure, the ceramic wavelength converter assembly comprising:
two first layers comprising an undoped host material or a doped host material;
two second layers comprising a barrier material; wherein the two second layers are disposed between the two first layers; and
a third layer comprising an undoped host material or a doped host material;
wherein the third layer is disposed between the two second layers;
wherein the two first layers comprise the undoped host material and the third layer comprises the doped host material, or
wherein the two first layers comprise the doped host material and the third layer comprises the undoped host material; and
wherein at least one of the two first layers comprise a patterned structure.

2. The ceramic wavelength converter assembly of claim 1, wherein the two first layers comprise the undoped host material and the third layer comprises the doped host material.

3. The ceramic wavelength converter assembly of claim 1, wherein the doped host material is a phosphor.

4. The ceramic wavelength converter assembly of claim 1, wherein the patterned structure is a regular patterned structure or a non-regular patterned structure.

5. The ceramic wavelength converter assembly of claim 1, wherein only one of the two first layers comprises a patterned structure.

6. The ceramic wavelength converter assembly of claim 1, wherein both of the two first layers comprise a patterned structure.

7. The ceramic wavelength converter assembly of claim 1, wherein the patterned structure comprises at least one structure element selected from the group consisting of triangle, rectangular, square, parallelogram, trapezoid, or a combination thereof.

8. A light emitting device comprising:
a light-emitting structure configured to emit a primary light having a first peak wavelength; and
a ceramic wavelength converter assembly positioned to receive the primary light from the light-emitting structure, the ceramic wavelength converter assembly comprising:
two first layers comprising an undoped host material or a doped host material;
two second layers comprising a barrier material; wherein the two second layers are disposed between the two first layers; and
a third layer comprising a doped host material, or an undoped host material;
wherein the third layer is disposed between the two second layers;
wherein the two first layers comprise the undoped host material and the third layer comprises the doped host material, or
wherein the two first layers comprise the doped host material and the third layer comprises the undoped host material; and
wherein at least one of the two first layers comprise a patterned structure.

9. The light emitting device of claim 8, wherein the at least one of the two first layers comprising the patterned structure is placed in close proximity to the light-emitting structure.

10. The light emitting device of claim 8, wherein both of the two first layers comprise the patterned structure.

11. The light emitting device of claim 8, wherein the patterned structure is a regular patterned structure or a non-regular patterned structure.

12. The light emitting device of claim 8, wherein the patterned structure comprises at least one structure element selected from the group consisting of triangle, rectangular, square, parallelogram, trapezoid, or a combination thereof.

13. The light emitting device of claim 8, wherein the doped host material is a phosphor.

14. A method for producing a ceramic wavelength converter assembly having a layered structure that includes two first layers, two second layers and a third layer, the method comprising:
providing the third layer comprising a doped host material or an undoped host material;
applying the second layer on an upper side of the third layer and applying the second layer on a lower side of the third layer; wherein the second layer comprises a barrier material;
applying the first layer on a side of each of the second layers furthest from the third layer, wherein the first layer comprises an undoped host material or a doped host material; and
patterning at least one of the two first layers;
wherein the two first layers comprise the undoped host material and the third layer comprises the doped host material, or
wherein the two first layers comprise the doped host material and the third layer comprises the undoped host material.

15. The method of claim 14, wherein the doped host material is a phosphor.

16. The method of claim 14, wherein patterning is made by chemical etching, sandblasting, dicing, laser machining, laser scribing, or a combination thereof.

17. Use of a ceramic wavelength converter assembly of claim 1 in a light emitting device.
